(19) United States
(12) Patent Application Publication
(10) Pub. No.: US 2023/0390886 A1
(43) Pub. Date: Dec. 7, 2023

(54) MONITORING OF ACOUSTIC EVENTS ON A SUBSTRATE

(71) Applicant: Applied Materials, Inc., Santa Clara, CA (US)

(72) Inventors: Upendra Ummethala, Cupertino, CA (US); Nicholas A. Wiswell, Sunnyvale, CA (US); David Masayuki Ishikawa, Mountain View, CA (US); Sohrab Pourmand, San Jose, CA (US); Benjamin Cherian, San Jose, CA (US); Thomas H. Osterheld, Mountain View, CA (US); Jeonghoon Oh, Saratoga, CA (US); Jianshe Tang, San Jose, CA (US)

(21) Appl. No.: 18/205,262

(22) Filed: Jun. 2, 2023

Related U.S. Application Data
(60) Provisional application No. 63/348,997, filed on Jun. 3, 2022.

(51) Int. Cl. B24B 37/013; H01L 21/66

(52) U.S. Cl. CPC B24B 37/013; H01L 22/26

(57) ABSTRACT

A chemical mechanical polishing apparatus, including a platen supporting a polishing pad; a carrier head to hold a surface of a substrate against the polishing pad; a motor to generate relative motion between the platen and the carrier head so as to polish an overlying layer on the substrate; an array of acoustic sensors arranged within the carrier head to receive acoustic signals from the surface of the substrate; and a controller configured to detect a position of an acoustic event on the surface of the substrate based on received acoustic signals from the array of acoustic sensors.

### CROSS-REFERENCE TO RELATED APPLICATIONS

This application claims the benefit of priority to U.S. Application No. 63/348,997, filed on Jun. 3, 2022, the contents of which are hereby incorporated by reference.

### TECHNICAL FIELD

This disclosure relates to in-situ monitoring of chemical mechanical polishing, and in particular to acoustic monitoring.

### BACKGROUND

An integrated circuit is typically formed on a substrate by the sequential deposition of conductive, semiconductive, or insulative layers on a silicon wafer. One fabrication step involves depositing a filler layer over a non-planar surface and planarizing the filler layer. For certain applications, the filler layer is planarized until the top surface of a patterned layer is exposed. A conductive filler layer, for example, can be deposited on a patterned insulative layer to fill the trenches or holes in the insulative layer. After planarization, the portions of the metallic layer remaining between the raised pattern of the insulative layer form vias, plugs, and lines that provide conductive paths between thin film circuits on the substrate. For other applications, such as oxide polishing, the filler layer is planarized, e.g., by polishing for a predetermined time period, to leave a portion of the filler layer over the nonplanar surface. In addition, planarization of the substrate surface is usually required for photolithography.

Chemical mechanical polishing (CMP) is one accepted method of planarization. This planarization method typically requires that the substrate be mounted on a carrier or polishing head. The exposed surface of the substrate is typically placed against a rotating polishing pad. The carrier head provides a controllable load on the substrate to push it against the polishing pad.

One problem in CMP is detecting the amount of material removed or exposure of an underlying layer of the substrate during an active polishing process. Various techniques to for in-situ monitoring have been proposed. For example, a substrate in contact with the polishing pad can be monitored by an optical sensor when the substrate passes over a window in the polishing pad. As another example, acoustic monitoring techniques with an acoustic sensor in the platen has been proposed.

### SUMMARY

Disclosed herein is a chemical mechanical polishing apparatus including an in-situ acoustic monitoring system arranged in a carrier head. Acoustic signals vary periodically during a polishing operation based on the interface between the substrate and the pad. Fluctuations in the layer thickness result in the underlying layer being exposed during the operation at different times. The acoustic monitoring system includes an array of acoustic sensors arranged in the carrier head which receive the acoustic signals from the substrate interface.

The acoustic monitoring system processes the received acoustic signals to detect certain acoustic events. For example, the location of a high amplitude acoustic event (e.g., an acoustic event having an intensity greater than one standard deviation from the average of the acoustic signal, or an acoustic event above a threshold intensity value) can be detected by the acoustic monitoring system by comparing the time the acoustic signal was received to each acoustic sensor and calculating a time-of-flight to each sensor based on the received signals.

As a second example, the array of acoustic sensors can be used to monitor various regions of the substrate surface during the polishing process. The acoustic signal received by each acoustic sensor of the array can be shifted by a pre-determined phase based on the region of the substrate surface to be monitored. Each shifted signal is then summed to approximate the acoustic signal generated by the region of the substrate.

In a first aspect, disclosed herein is a chemical mechanical polishing apparatus, including a platen supporting a polishing pad; a carrier head to hold a surface of a substrate against the polishing pad; a motor to generate relative motion between the platen and the carrier head so as to polish an overlying layer on the substrate; an array of acoustic sensors arranged within the carrier head to receive acoustic signals from the surface of the substrate; and controller configured to detect a position of an acoustic event on the surface of the substrate based on received acoustic signals from the array of acoustic sensors.

Examples can include the following features. The controller can be further configured to detect the position of the acoustic event on the surface of the substrate based on time-of-flight calculations of received acoustic signals from each of the acoustic sensors of the array. The array of acoustic sensors can include three or more acoustic sensors. The acoustic sensor can receive acoustic signals in a frequency range from 10 kHz to 200 kHz. The acoustic sensor can be a passive acoustic sensor.

In a second aspect, disclosed herein is a chemical mechanical polishing apparatus, including a platen to support a polishing pad; a carrier head to hold a surface of a substrate against the polishing pad; a motor to generate relative motion between the platen and the carrier head so as to polish an overlying layer on the substrate; an array of acoustic sensors arranged within the carrier head to receive acoustic signals from the surface of the substrate; and controller configured to detect a position on the substrate at which a polishing endpoint has been reached based on received acoustic signals.

Examples can include the following features. The controller can be configured to determine the position by performing beamforming of the received acoustic signals. The controller can be configured to perform beamforming by applying a phase shift to each of the received acoustic signals and summing the phase-shifted received acoustic signals to detect a polishing endpoint in a zone. The controller can be configured to, for each respective position of a plurality of positions on the substrate, apply a respective set of phase shifts to the received acoustic signals and sum the phase-shifted received acoustic signals to generate a summed signal that can be beamformed to selectively represent acoustic activity at the respective position on the substrate, thus generating a plurality of summed signals that represent the plurality of positions. The controller can further include monitoring each respective summed signal of the plurality of summed signals for a change in the respective summed signal that represents a polishing endpoint at the respective position corresponding to the respective summed signal. The polishing endpoint can include removal of a layer being polished to expose an underlying layer. The controller further configured to, prior to detect a polishing endpoint in a zone, denoise the received acoustic signals from the array of acoustic sensors. The array of acoustic sensors can include five or more acoustic sensors. Particular implementations of the subject matter described in this specification can be implemented so as to realize one or more of the following technical advantages.

One or more of the following possible advantages may be realized. Wafer-to-wafer (WTW) and within-wafer (WIW) polishing uniformity can be improved. Detection of the location of high amplitude acoustic events enables real-time monitoring of a region where an underlying layer is being exposed without requiring that the sensor actually pass below the region. Monitoring of various regions of the substrate surface allows in-situ pressure control to achieve higher planarization uniformity. Detection of the location of high amplitude acoustic events also enables monitoring of the formation of defects on the substrate surface.

The details of one or more embodiments are set forth in the accompanying drawings and the description below. Other features and advantages will be apparent from the description and drawings, and from the claims.

### DESCRIPTION OF DRAWINGS

FIG. 1 illustrates a schematic cross-sectional view of an example of a polishing apparatus.

FIG. 2 illustrates a perspective cross-sectional view of a carrier head.

FIG. 3A is a bottom view of a carrier head.

FIG. 3B illustrates a close up view of the two exemplary acoustic sensors of FIG. 3A.

FIGS. 3C and 3D illustrate an acoustic sensor mounted in a retractable waveguide.

FIGS. 4A and 4B is a schematic view of two arrangements of acoustic sensors in a carrier head.

FIGS. 5A and 5B schematically illustrate detecting a high amplitude acoustic events.

FIGS. 6A and 6B illustrate respective implementations for dividing a substrate into multiple acoustic monitoring zones.

FIGS. 6C illustrates monitoring an acoustic monitoring zone using acoustic sensors in a carrier head.

FIGS. 6D and 6E illustrate signal processing for monitoring an acoustic monitoring zone based on independent received acoustic signals.

In the figures, like references indicate like elements.

### DETAILED DESCRIPTION

In some semiconductor chip fabrication processes, an overlying layer, e.g., metal, silicon oxide or polysilicon, is polished until patterned features of an underlying layer, e.g., a dielectric, such as silicon oxide, silicon nitride or a high-K dielectric, are exposed. Reliable detection of exposure of the underlying layer can be difficult and subject to ever increasing requirements for precision and accuracy.

The carrier head induces motion between the substrate and the polishing pad atop the platen. Acoustic emissions are generated as the substrate is swept over the asperities of the polishing pad. The acoustic emissions originate from the interface between the substrate surface and the polishing pad and vary with time according to the polishing stage and material exposed on the substrate surface.

Placement of an acoustic sensor in the platen to monitor signals that propagate through the polishing pad has been proposed. However, a polishing system including acoustic sensors arranged in the platen is only able to effectively receive acoustic signals when the platen sweeps the acoustic sensor beneath the substrate; when the sensor is not below the substrate the signal needs to propagate laterally through the polishing pad so that noise generally overwhelms any signal. Although such a system generates acoustic measurements at regular intervals, there are periods when no signal is available.

In contrast, an acoustic monitoring system including an array of acoustic sensors within the carrier head can continuously receive acoustic signals corresponding with the acoustic emissions. The received acoustic signals from the array of sensors can be processed individually to monitor the surface of the substrate in real-time. Alternatively or in addition, the received acoustic signals can be processed in parallel to determine information about endpoints, e.g., exposure of an underlying layer, during polishing of the substrate. In particular, the location at which exposure of an underlying layer is occurring can be calculated based on the received acoustic signals.

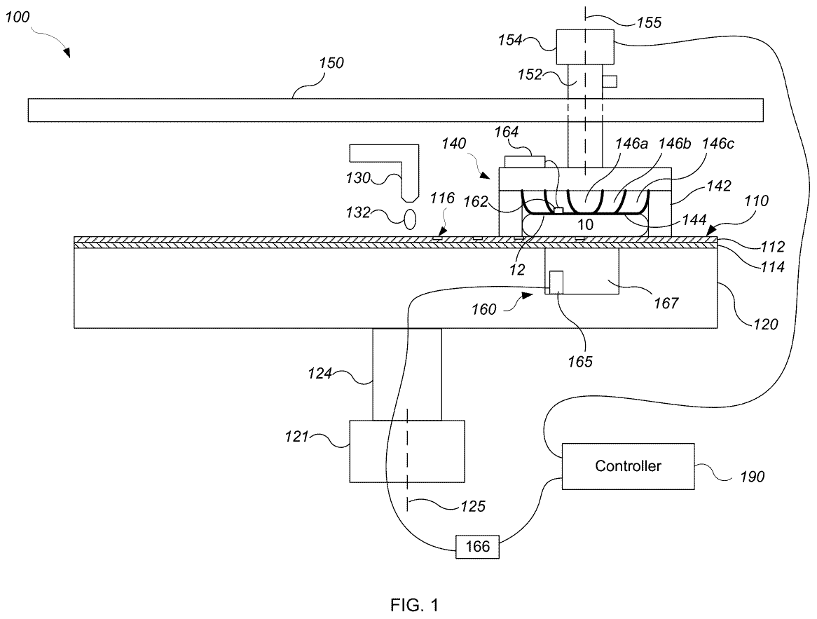

FIG. 1 illustrates an example of a polishing apparatus 100. The polishing apparatus 100 includes a rotatable disk-shaped platen 120 on which a polishing pad 110 is situated. The polishing pad 110 can be a two-layer polishing pad with an outer polishing layer 112 and a softer backing layer 114. The platen is operable to rotate about an axis 125. For example, a motor 121, e.g., a DC induction motor, can turn a drive shaft 124 to rotate the platen 120.

The polishing apparatus 100 can include a port 130 to dispense polishing liquid 132, such as abrasive slurry, onto the polishing pad 110 to the pad. The polishing apparatus can also include a polishing pad conditioner to abrade the polishing pad 110 to maintain the polishing pad 110 in a consistent abrasive state.

The polishing apparatus 100 includes at least one carrier head 140. The carrier head 140 is operable to hold a substrate 10 against the polishing pad 110. The carrier head 140 can include a retaining ring 142 to retain the substrate 10 below a flexible membrane 144. The carrier head 140 also includes one or more independently controllable pressurizable chambers defined by the membrane, e.g., three chambers 146a-146c, which can apply independently controllable pressurizes to associated zones on the flexible membrane 144 and thus on the substrate 10 (see FIG. 1). Although only three chambers are illustrated in FIG. 1 for ease of illustration, there could be one or two chambers, or four or more chambers, e.g., five chambers.

The carrier head 140 is suspended from a support structure 150, e.g., a carousel or track, and is connected by a drive shaft 152 to a carrier head rotation motor 154, e.g., a DC induction motor, so that the carrier head can rotate about an axis 155. Optionally each carrier head 140 can oscillate laterally, e.g., on sliders on the carousel 150, or by rotational oscillation of the carousel itself, or by sliding along the track. In typical operation, the platen is rotated about its central axis 125, and each carrier head is rotated about its central axis 155 and translated laterally across the top surface of the polishing pad.

A controller 190, such as a programmable computer, is connected to the motors 121, 154 to control the rotation rate of the platen 120 and carrier head 140. For example, each motor can include an encoder that measures the rotation rate of the associated drive shaft. A feedback control circuit, which could be in the motor itself, part of the controller, or a separate circuit, receives the measured rotation rate from the encoder and adjusts the current supplied to the motor to ensure that the rotation rate of the drive shaft matches at a rotation rate received from the controller.

The polishing apparatus 100 includes at least one in-situ acoustic monitoring system 160. The in-situ acoustic monitoring system 160 includes one or more acoustic sensors 162. Each acoustic sensor 162 is installed at a respective location in the carrier head 140. The in-situ acoustic monitoring system 160 can be configured to detect acoustic emissions caused by the interface between the substrate 10 and the pad 110, e.g., when exposing the features of the underlying layer when the material of the substrate 10 is removed.

In the implementation shown in FIG. 1, the acoustic monitoring system 160 includes an acoustic sensor 162 positioned within and supported by the carrier head 140 to receive acoustic signals from the substrate 10. In some implementations, the acoustic monitoring system 160 includes an array of acoustic sensors 162, e.g., more than one acoustic sensor 162. In such examples, each acoustic sensor 162 of the array receives a respective acoustic signal. For example, the acoustic monitoring system 160 can include three or more, or five or more acoustic sensors 162, with each sensor receiving an acoustic signal that varies based on the location of the acoustic sensor 162 within the carrier head 140.

The acoustic sensors 162 of the acoustic monitoring system 160 are connected to a wireless transmitter 164. The acoustic sensors 162 each receive an acoustic signals and transmit the signals to the transmitter 164. The acoustic sensors 162 can be in wired, or wireless, connection with the transmitter 164.

The transmitter 164 transmits the received acoustic signals to a wireless receiver 165, e.g., arranged within a recess 167 of the platen 120, which is in turn connected to the controller 190. The receiver 165 can be arranged in alternative locations within signal range of the transmitter 164. For example, the receiver 165 can be supported by the support structure 150, on the drive shaft 124, or within the polishing chamber of the apparatus 100. The transmitter 164 and receiver 165 can operate on any functional wireless frequency, such as Bluetooth™, or Wi-Fi, e.g., 2.4 gigahertz (GHz), or 5 GHz. Alternatively, the acoustic sensor 162 can be connected by circuitry to the controller 190, to a power supply and/or to other signal processing electronics 166 through a rotary coupling, e.g., a mercury slip ring.

The acoustic sensor 162 is a contact acoustic sensor 162 having a surface coupled to (e.g., in direct contact with) the back surface 12 of the substrate 10, i.e., the surface on the side of the substrate farther from the pad 110. The acoustic sensor 162 can be, for example, an electromagnetic acoustic transducer or piezoelectric acoustic transducer. A piezoelectric sensor can include a rigid contact plate, e.g., of stainless steel or the like, which is placed into contact with the body to be monitored, and a piezoelectric assembly, e.g., a piezoelectric layer sandwiched between two electrodes, on the backside of the contact plate.

In some implementations, the in-situ acoustic monitoring system 160 is a passive acoustic monitoring system. In this case, signals are monitored by the acoustic sensor 162 without generating signals from an acoustic signal generator (or the acoustic signal generator can be omitted entirely from the system). The passive acoustic signals monitored by the acoustic sensor 162 can be in 50 kHz to 1 MHz range, e.g., 10 kHz to 200 kHz, 200 to 400 kHz, or 200 KHz to 1 MHz. For example, for monitoring of polishing of inter-layer dielectric (ILD) in a shallow trench isolation (STI), a frequency range of 225 kHz to 350 kHz can be monitored.

The signal from the sensor 162 can be amplified by a built-in internal amplifier. In some implementations, the amplification gain is between 40 and 60 dB (e.g., 50 dB). The signal from the acoustic sensor 162 can then be further amplified and filtered if necessary, and digitized through an A/D port to a high speed data acquisition board, e.g., in the electronics 166. Data from the acoustic sensor 162 can be recorded at a similar range as that of the generator 163 or at a different, e.g., higher, range, e.g., from 1 to 10 MHz, e.g., 1-3 MHz or 6-8 MHz. In implementations in which the acoustic sensor 162 is a passive acoustic sensor, a frequency range from 100 kHz to 2 MHz can be monitored, such as 500 kHz to 1 MHz (e.g., 750 kHz).

Positioned in the carrier head 140, the acoustic sensors 162 can be attached to, or embedded within, the retaining ring 142 or the chamber membrane 144. Positioning the acoustic sensors 162 on the membrane 144 but substantially the maximum possible radial distance from the central axis 155 can increase the time-of-flight of acoustic signals generated from the substrate 10 surface (relative to sensors placed closer to the central axis 155). Increased time-of-flight can make signal differentiation from independent acoustic sensors 162 easier and thus increase the location accuracy of detected acoustic events.

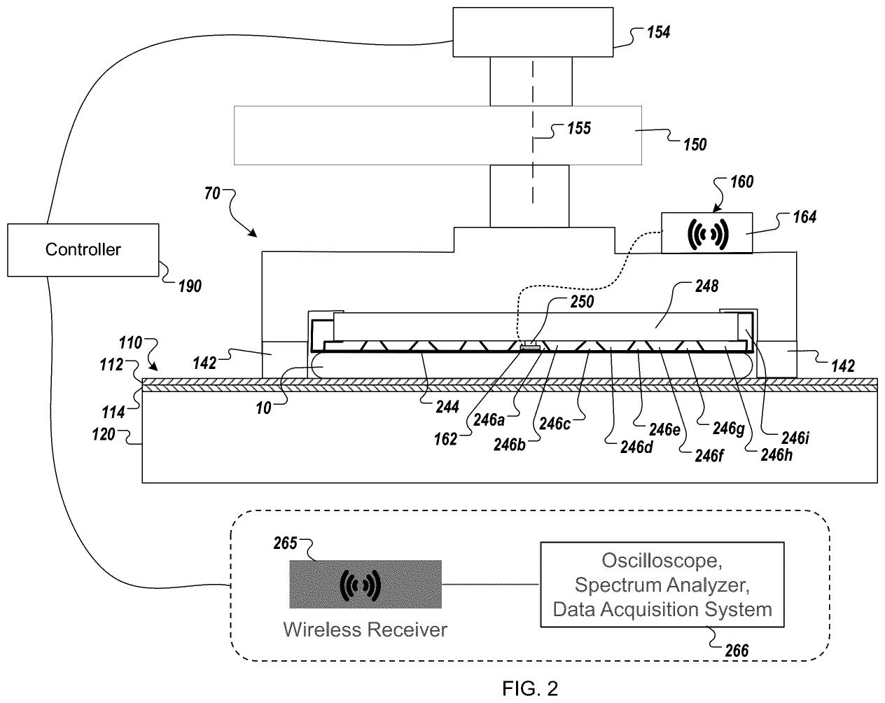

Positioning the acoustic sensors 162 within the membranes of the chambers 146a-146c facilitates increased density of the acoustic sensors 162 and increased location accuracy of detected acoustic events. Referring now to FIG. 2, an exemplary carrier head 140 is illustrated including an acoustic monitoring system 160. The carrier head 140 includes a retaining ring 142 enclosing a substrate 10, and a flexible membrane 144 in contact with a back surface of the substrate 10.

The membrane 144 is composed of a chemically- and water-resistant, flexible material which contacts the surface of the substrate 20 on the side of the substrate further from the pad 110. For example, the membrane 144 can be composed of polymeric materials such as silicone, polycarbonate, or polyurethane.

The membrane 144 is separates the volume between a carrier body 248 and the membrane 244 into multiple chambers, for example, chambers 246a-246i. The carrier body 248 can be fixed relative to the drive shaft, or could be vertically movable relative to a housing that is fixed to the drive shaft. These chamber can be radially symmetric around the central axis 155. The air pressure within each of the chambers 246a-246i is independently controllable by a connected controller 190. The membrane 144 is affixed to the carrier head 140, e.g., by clamp rings which clamp flaps of the membrane to the carrier body 248. The controller 190 modulates the air pressure applied by one or more pressure sources to each of the chambers 246a-246i to apply positive or negative pressure to the substrate 10 in a specific annular region. Specifically, positive pressure results in the annular region of each of the chambers 246a-246i pressing the substrate 10 against the pad 110, which negative pressure results in the annular regions pulling the substrate 10 against the carrier head 140.

The acoustic monitoring system 160 of FIG. 2 includes the transmitter 164 connected to the acoustic sensor 162. The acoustic sensor 162 is illustrated as installed in a chamber 246a through which the central axis 255 passes. The acoustic sensor 162 can receive acoustic signals from the substrate 10 when installed. In some implementations, the acoustic sensor 162 contacts the inner surface of the membrane 244, i.e., the surface of the membrane farther from the substrate 10, to receive acoustic signals transmitted through the membrane from the substrate 10. For example, the sensor 162 can be supported on a support structure 248, which can be attached to or be part of the support plate within the carrier head to which the flaps of the membrane are clamped. In alternative implementations the acoustic sensor 162 is molded into the membrane 244. The sensor 162 can be embedded in and covered by the membrane 244, or can be set into the membrane 244 with an exposed surface to directly contact the substrate 10.

In further alternative embodiments, the membrane is manufactured with a transmissive element which increases acoustic signal transmission through the membrane 244 to the acoustic sensor 262 in contact with the transmissive element. Examples of transmissive elements can include a wire, or a foil antenna.

Acoustic signals generated by the interface between the substrate 10 and the polishing layer 112 of the pad 110 travel through the substrate 10 and are received by the acoustic sensor 162. The acoustic sensor 162 transmits the received acoustic signals to the connected transmitter 164. The transmitter 164 transmits the acoustic signal to the receiver 265. The receiver 265 is connected to signal processing electronics 266 which perform functions on the received acoustic signal. The electronics 266 can include, for example, an oscilloscope, a spectrum analyzer, a data acquisition system (DAQ), or other components for processing the received acoustic signal. In some implementations, the electronics 266 is within the controller 190.

FIG. 2 also illustrates the receiving circuitry of the acoustic monitoring system 260 including the receiver 265 and electronics 266. The receiver 265 is connected to signal processing electronics 266 which perform functions on the received acoustic signal. The electronics 266 can include, for example, an oscilloscope, a spectrum analyzer, a data acquisition system (DAQ), or other components for processing the received acoustic signal. In some implementations, the electronics 266 is within the controller 190. In general, the electronics 266 can include a general purpose programmable computer, dedicated circuitry, or a combination thereof.

The electronics 266 performs signal processing of and/or calculations based on the received acoustic signals. The calculations can include determinations of one or more parameters of the acoustic signals. Examples of parameters of the acoustic signals can include a phase, a time of arrival, a frequency spectrum, or a power spectrum. The electronics 266 connect with and transmit information to the controller 190. The electronics 266 can transmit the acoustic signals, one or more parameters of the acoustic signals, or both, to the controller 190. In some implementations, the calculations are performed directly by the controller 290.

In some implementations, the controller 190 controls one or more components of the apparatus 100, such motors that control rotation rates of the carrier head 140 or platen 220 or pressure controllers that control pressures within the chambers 246a-246i based on the received acoustic signals.

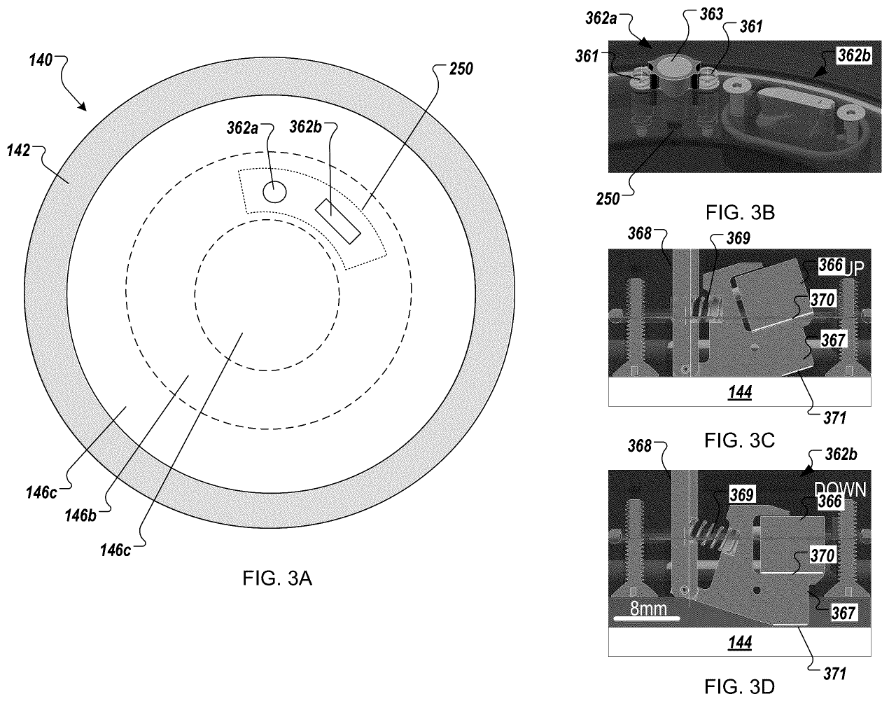

Referring now to FIG. 3A, a bottom view of an example carrier head 140 is shown having two acoustic sensors of two different configurations, acoustic sensor 362a and acoustic sensor 362b, arranged on the support structure 250 (see FIGS. 2 and 3B) in the carrier head 140. Although FIG. 3A illustrates a carrier head with both sensors, the carrier head could have just one of the sensors, or multiple sensors of one type but not the other (e.g., multiple sensors of the configuration of acoustic sensor 362a). In addition, although FIG. 3A illustrates three chambers, there could be one or two, or four or more chambers. In addition, although FIG. 3A illustrates the sensors 362a, 362b in a middle chamber, the sensors could be located in a different chamber, e.g., an innermost or outermost chamber. In addition, although FIG. 3A illustrates the sensors 362a, 362b in the same chamber, the sensors could be positioned in different chambers.

The carrier head 140 includes the retaining ring 142 surrounding the inner components. The support structure 346 is a rigid structure of the carrier head 140 which supports and houses additional components. The support structure 346 holds one or more membrane support 348 to which the membrane 144 is affixed. The membrane 144 is not shown in FIG. 3A and 3B but is described with reference to FIGS. 3C and 3D.

FIG. 3B is a schematic perspective view of the two acoustics sensors 362a, 362b. Acoustic sensor 362a is a direct contact acoustic sensor which extends from the surface of the support structure 250. Acoustic sensor 362a includes two springs 361 that urge the acoustic sensor 362a against the membrane 144 (not shown, but upward in FIG. 3B). The springs 361 can be positioned between the support structure 250 and flanges that extend from the sensor 362a.

The extension force is sufficiently high to maintain contact with the membrane 144 when positive atmospheric pressure within whichever the chamber the sensor is positioned has pressed the membrane 144 away from the support structure 346 and against the substrate 10 carrier head 140. On the other hand, the extension force is sufficiently low such that when negative atmospheric pressure within the chambers draws the membrane 144 against the support structure 346, the acoustic sensor 362a retracts such that the contact surface 363 is coplanar with the support structure 346.

Acoustic sensor 362b is a second acoustic sensor arrangement in which the associated acoustic sensor is movable between a recessed position and an extended position, shown in FIGS. 3C and 3D, respectively. Referring now to FIGS. 3C and 3D, the acoustic sensor 362b includes a contact sensor 366 mounted on a waveguide 367. The waveguide 367 pivots at a corner affixed to a base 368 arranged within the support structure 346. A spring 369 provides a force which extends the waveguide 367 to the extended state (FIG. 3D) when the membrane 144 is away from the support structure 346, and retracts the waveguide 367 to the retracted state (FIG. 3C) when the membrane 144 is contacted to support structure 346, e.g., as in during vacuum chucking of the substrate to the carrier head 140.

The waveguide 367 being movable between a first and a second position provides flexibility to the polishing process. During steps in which the sensor 362b is retracted, e.g., due to vacuum being applied within the chamber so that the membrane 144 contacts and drives the waveguide 367 to pivot upwardly, the sensing surface 371 is no longer in direct contact with the membrane. When the waveguide 367 is in the extended state, the sensing surface 371 has a low surface area, reducing the overall pressure of the waveguide 367 through the membrane 144 and reducing the likelihood of polishing non-uniformity. This may also increase the spatial resolution of the received acoustic signals.

The waveguide 367 includes a contact surface 370 and a sensing surface 371. The contact sensor 366 contacts the contact surface 370. When in the extended position, the sensing surface 371 contacts the membrane 144. Acoustic signals generated from the polishing of a substrate within the carrier head 140 travel through the membrane 144 and are received by the sensing surface 371. The signals are transmitted through the waveguide 367 to the contact surface 370 and received by the contact sensor 366.

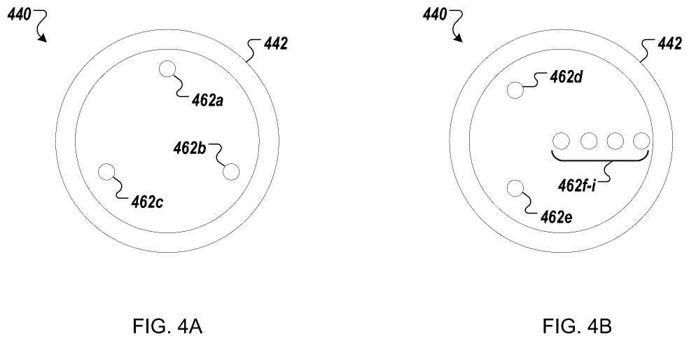

The two acoustic sensors, acoustic sensor 362a and acoustic sensor 362b, are positioned at exemplary positions within the support structure 346. Acoustic sensors within the carrier head 140 can be arranged at positions for monitoring different areas of the carrier head 140, such as the arrangements described further in FIGS. 4A and 4B.

FIGS. 4A and 4B illustrate two exemplary configurations of arrays of acoustic sensors arranged within a carrier head. FIG. 4A depicts an array of three acoustic sensors, including acoustic sensors 462a-462c. The array of acoustic sensors 462a-462c is disposed in a triangular arrangement with the distance between the acoustic sensors 462a-462c being approximately equal, e.g., an equilateral triangle.

FIG. 4B depicts a second exemplary array of six acoustic sensors, including acoustic sensors 462d-462i. Acoustic sensor 462d and acoustic sensor 462e are spaced apart from acoustic sensors 462f-462i. Acoustic sensors 462f-462i are arranged along a common centerline, e.g., linearly. Arrangements of the acoustic sensors 462d-462i can provide independent function based on the arrangement. For example, the acoustic sensors 426d, 462e, and 462i approximate the arrangement of acoustic sensors 462a-462c. In such implementations, acoustic sensors 426d, 462e, and 462i can provide information for triangulation of acoustic events while acoustic sensors 426f-h can provide localized information related to acoustic monitoring zones beneath the sensors. In general, the process of triangulation includes locating an acoustic event by accurately computing the time difference of arrival (TDOA) of a signal emitted from the object to three or more receivers.

The acoustic monitoring system 160 receives acoustic signals from the acoustic sensors 162 generated by the substrate 10 (e.g., the interface between the substrate 10 and the pad 110). During some polishing operations, high amplitude acoustic events can occur and are received by the acoustic monitoring system 160. High amplitude acoustic events can include. In some implementations, the acoustic monitoring system 160 can receive the acoustic signal corresponding to an acoustic event at multiple acoustic sensors 162 and determine an estimated location at which the acoustic signal was generated, e.g., detecting the position of the acoustic event.

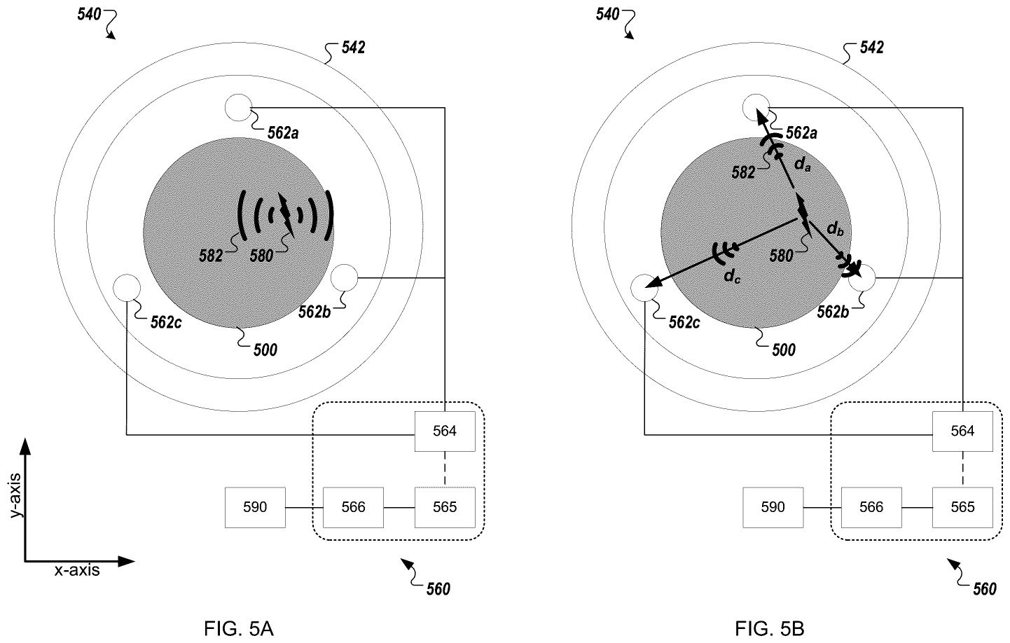

Referring to FIGS. 5A and 5B, a carrier head 540 is illustrated having a substrate 500 within the retaining ring 542. The carrier head 540 includes three acoustic sensors 562a-562c arranged in the array of FIG. 4A, e.g., in a triangular array. The acoustic sensors 562a-562c connect to the transmitter 564 and receiver 565 of the acoustic monitoring system 560. As shown in FIG. 5A, the substrate 500 includes a defect 580 generating a high amplitude acoustic event 582. The acoustic event 582 propagates outward from the defect 580.

FIG. 5B shows the acoustic event 582 propagating outward from the defect 580. The location of the defect 580 is a distance from each of the acoustic sensors 562a-562c; dₐ, d_{b}, and d_{c}, respectively. Each acoustic sensors 562a-562c receives the acoustic event 582 at a different time, tₐ, t_{b}, and t_{c}. The distance that the acoustic event 582 propagates to each of the acoustic sensors 562a-562c is different based on the locations of the acoustic sensors 562a-562c within the carrier head 540, e.g., dₐ≠d_{b}≠d_{c}. As such, the times the acoustic sensors 562a-562c receive the acoustic event 582 are different, e.g., tₐ≠t_{b}≠t_{c}.

The acoustic sensors 562a-562c sends the received acoustic signals to the transmitter 564 which transmits the acoustic signals to the receiver 565. The receiver 565 transmits the acoustic signals to the electronics 566 and controller 590.

The electronics 566 receives the acoustic signals and performs calculations on the signals. In some implementations, the electronics 566 calculates a location of the defect 580 on the substrate 500 based on the received acoustic signals. For example, the electronics 566 uses the times the acoustic sensors 562a-562c receive the acoustic event 582 to perform triangulation, e.g., triangulation, calculations to determine the location of the defect 580.

Given a defect 580 generating an acoustic event 582 at an unknown location (e.g., E=(x, y, z)) on the substrate 500 within range of Pₙ receivers at known locations (e.g., Pᵢ=Pₓ, P_{y}, Pₜ), e.g., the acoustic sensors 562a-562c. Without wishing to be bound by theory, the distance Rₘ from the emitter to one of the receivers in terms of Cartesian coordinates is Rₘ=\sqrt{(pₓ−x)²−(P_{y}−y)²−(P_{z}−z)²}.

The distance Rₘ is the wave speed, c, times the transit time from the defect 580 to the one of the acoustic sensors 562a-562c. The time difference of the acoustic event 582 touching each of the acoustic sensors 562a-562c, e.g., T=tᵢ−tₒ, are calculated by the electronics 566 based on the receiver. The distance to each of the acoustic sensors 562a-562c is then calculated based on the time difference. The distance to each of the acoustic sensors 562a-562c is used to calculate the location of the defect 580 on the substrate 500. Locating the defect 580 aids in wafer-to-wafer, and within-wafer quality control for the polishing process.

In some implementations, the acoustic monitoring system 160 monitors a region of the substrate 10 using the array of acoustic sensors 162. The acoustic monitoring system 160 beamforms the acoustic signals received by the acoustic sensors 162 to acoustically isolate the acoustic signal generated by a region of the substrate 10. Beamforming is an acoustic technique which is applied to received acoustic signals to monitor a spatial location for acoustic activity or events at a distance from the array of acoustic sensors 162.

In some implementations, a phase shift, e.g., a time delay, is applied to each of the acoustic signals received by the acoustic sensors 162 such that the phase shift correlates with the distance from the acoustic sensors 162 of a region to be monitored. The phase-shifted signals are then summed to create a summed signal. Applying phase shifts to each received acoustic signal to detect acoustic activity at a particular region is termed ‘beamforming.’ This can amplify the acoustic signal, whether an acoustic event or acoustic activity, generated at the selected region.

The amount of phase shift applied to each of the acoustic signals can vary over time. In particular, the phase shifts can be varied such that the spatial region provided by the beamforming is “scanned” across the all of the wafer, or a region of the wafer, at a predetermined interval.

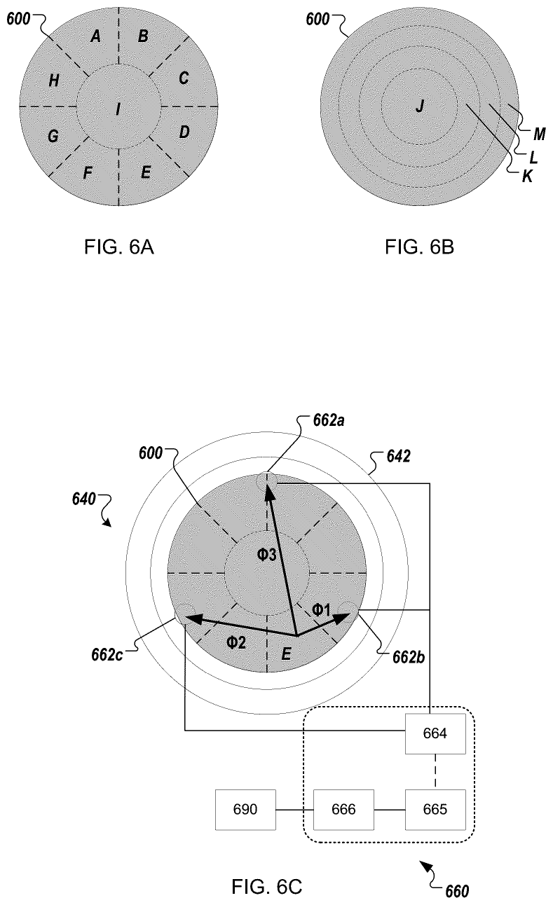

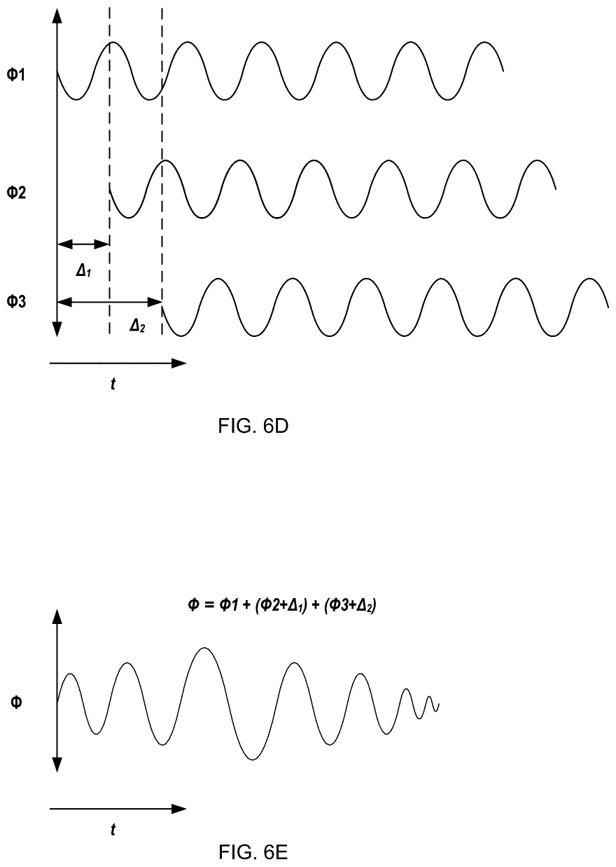

FIGS. 6A and 6B illustrate an example substrate 600, such as substrate 10 or substrate 500, divided into a number of monitoring zones. The dashed lines illustrated on the substrate 600 of FIGS. 6A and 6B are representative of illustrative examples of dividing the independent acoustic monitoring zones.

FIG. 6A illustrates the substrate 600 divided into monitoring zones A-I. Monitoring zones A-H are radial sections of a portion of the circumference of the substrate 600 while monitoring zone I is a circular section surrounding the center of the substrate 600. FIG. 6B illustrates the substrate 600 divided into monitoring zones J-M. Monitoring zones K-M are concentric annular rings surrounding the substrate 600 center while monitoring zone J is a circular section surrounding the center of the substrate 600, such as monitoring zone I.

The monitoring zones of FIGS. 6A and 6B are exemplary and alternative monitoring zone divisions can be achieved through appropriate signal processing of the received acoustic signals. The signal processing can be performed in the controller 190 or the signal processing electronics 166. In implementations in which the signal processing electronics 166 perform the beamforming, the signal processing electronics 166 can send the summed signal to the controller 190 for modification of one or more polishing parameter of the polishing operation, such as a pressure in one or more chambers 146a-146c. In alternative embodiments, the monitoring zones can be regular or irregular arrays of shapes covering at least a portion of the substrate 600 surface, e.g., a rectangular grid.

FIG. 6C illustrates the substrate 600 within the retaining ring 642 of a carrier head 640. Each acoustic monitoring zone of the substrate 600 is arranged at a distance from each of the acoustic sensors 662a-662c. For example, acoustic monitoring zone E is shown in FIG. 6C and arrows representing acoustic signals Φ1-Φ3 illustrate the respective path an acoustic signal, Φ, follow to reach the acoustic sensors 662a-662c.

The acoustic signal, Φ, is generated at acoustic monitoring zone E. The acoustic signal, Φ, travels from acoustic monitoring zone E to each of the acoustic sensors 662a-662c along a different path having respective lengths. Acoustic sensor 662b receives acoustic signal Φ at a first time based on the distance of acoustic sensor 662b from acoustic monitoring zone E, and acoustic sensor 662c and acoustic sensor 662a receive acoustic signal 12 and 13, respectively, at times based on the distance from acoustic monitoring zone E.

The acoustic sensors 662a-662c transmit the received acoustic signals Φ1-Φ3 to the transmitter 664 of the acoustic monitoring system 660 which is sent to the receiver 665 and electronics 666. FIG. 6D is a chart which depicts the acoustic signals Φ1-Φ3 received by the electronics 666 at different times. The acoustic signals Φ1-Φ3 are shown along the y-axis while time is shown along the x-axis. Acoustic signal Φ1 is received at a first time, acoustic signal Φ2 is received at a second time having a phase offset of Δ1, and acoustic signal Φ3 is received at a third time having a phase offset of Δ2.

The electronics 666 receives the acoustic signals Φ1-Φ3 and applies a phase offset to acoustic signal Φ2 and acoustic signal Φ3 of Δ1 and Δ2 respectively to approximate the acoustic signals Φ1-Φ3 generated at acoustic monitoring zone E being received at acoustic sensors 662a-662c simultaneously. The phase-shifted acoustic signals, e.g., (Φ2+Δ1) or (Φ3+Δ2), can then be summed into a summed signal representing the acoustic signal Φ generated at acoustic monitoring zone E, e.g., Φ=Φ1+(Φ2 +Δ1)+(Φ3+Δ2)

The summed signal can include constructive, or destructive, interferences based on the received acoustic signals Φ1-Φ3. The interferences can represent various acoustic events, or acoustic activity, from the acoustic monitoring zone, such as detection of a layer transition, a defect, or a scratch. In some implementations, the controller 690 can vary a polishing parameter of the carrier head 640 based on the detected acoustic event. For example, the controller 690 can vary a pressure within the chambers 146a-146c, or rotation rate of the controller 690, based on the detected acoustic event, such as a layer transition.

In some implementations, the electronics 666 can apply additional signal processing to the received signals, such as acoustic signals Φ1-Φ3. The received acoustic signals, or summed signals, can be summed, filtered, amplified, correlated, de-noised, or transformed into a second dimension. For example, the received signals, or summed signal, can be transformed into a frequency dimension before or after other signal processing. A Fourier transformation, such as a Fast Fourier transformation, can be applied to the received signals, or summed signal.

The electronics 666 or controller 690 can store in memory or storage, an array of phase offsets, Δ, for each of the acoustic sensors 662a-662c based on the distance to each of the acoustic monitoring zones, such as the acoustic monitoring zones of FIG. 6A or 6B. The electronics 666 or controller 690 can then receive acoustic signals from each acoustic sensors 662a-662c and apply a phase offset, Δ, to each received acoustic signal based on the distance to the acoustic monitoring zone to be monitored. The acoustic monitoring zones can be monitored independently, consecutively, or in parallel.

While this specification contains many details, these should not be construed as limitations on the scope of what may be claimed, but rather as descriptions of features specific to particular examples. Certain features that are described in this specification in the context of separate implementations can also be combined. Conversely, various features that are described in the context of a single implementation can also be implemented in multiple embodiments separately or in any suitable subcombination.

A number of implementations have been described. Nevertheless, it will be understood that various modifications may be made without departing from the spirit and scope of the invention. Accordingly, other implementations are within the scope of the following claims.

What is claimed is:

1. A chemical mechanical polishing apparatus, comprising:
a platen supporting a polishing pad;
a carrier head to hold a surface of a substrate against the polishing pad;
a motor to generate relative motion between the platen and the carrier head so as to polish an overlying layer on the substrate;
an array of acoustic sensors arranged within the carrier head to receive acoustic signals from the surface of the substrate; and
a controller configured to detect a position of an acoustic event on the surface of the substrate based on received acoustic signals from the array of acoustic sensors.

2. The apparatus of claim 1, wherein the controller is further configured to detect the position of the acoustic event on the surface of the substrate based on time-of-flight calculations of received acoustic signals from each of the acoustic sensors of the array.

3. The apparatus of claim 1, wherein the array of acoustic sensors includes three or more acoustic sensors.

4. The apparatus of claim 1, wherein the acoustic sensor receives acoustic signals in a frequency range from 10 kHz to 200 kHz.

5. The apparatus of claim 1, wherein the acoustic sensor is a passive acoustic sensor.

6. A chemical mechanical polishing apparatus, comprising:
a platen to support a polishing pad;
a carrier head to hold a surface of a substrate against the polishing pad;
a motor to generate relative motion between the platen and the carrier head so as to polish an overlying layer on the substrate;
an array of acoustic sensors arranged within the carrier head to receive acoustic signals from the surface of the substrate; and
a controller configured to detect a position on the substrate at which a polishing endpoint has been reached based on received acoustic signals.

7. The apparatus of claim 6, wherein the controller is configured to determine the position by performing beamforming of the received acoustic signals.

8. The apparatus of claim 7, wherein the controller is configured to perform beamforming by applying a phase shift to each of the received acoustic signals and summing the phase-shifted received acoustic signals to detect a polishing endpoint in a zone.

9. The apparatus of claim 7, wherein the controller is configure to, for each respective position of a plurality of positions on the substrate, apply a respective set of phase shifts to the received acoustic signals and sum the phase-shifted received acoustic signals to generate a summed signal that is beamformed to selectively represent acoustic activity at the respective position on the substrate, thus generating a plurality of summed signals that represent the plurality of positions.

10. The apparatus of claim 9, comprising monitoring each respective summed signal of the plurality of summed signals for a change in the respective summed signal that represents a polishing endpoint at the respective position corresponding to the respective summed signal.

11. The apparatus of claim 6, wherein the polishing endpoint comprises removal of a layer being polished to expose an underlying layer.

12. The apparatus of claim 6, the controller further configured to, prior to detect a polishing endpoint in a zone, denoise the received acoustic signals from the array of acoustic sensors.

13. The apparatus of claim 6, wherein the array of acoustic sensors includes five or more acoustic sensors.

14. A method of polishing, comprising:
holding a substrate with a carrier head and bringing a surface of a substrate into contact with a polishing pad;
generating relative motion between the substrate and the polishing pad;
monitoring acoustic signals from the substrate from a plurality of sensors in the carrier head;
calculating a position of an acoustic event on the surface of the substrate based on the acoustic signals received from the plurality of sensors. The method of claim 14, wherein calculating the position is based on time-of-flight calculations of received acoustic signals from each of the acoustic sensors of the array.

16. The method of claim 14, wherein the plurality of sensors monitor acoustic signals in a frequency range from 10 kHz to 200 kHz.

17. The method of claim 14, wherein monitoring comprises passive monitoring using passive acoustic sensors.
